(19) United States
(12) Patent Application Publication
(10) Pub. No.: US 2023/0163203 A1
(43) Pub. Date: May 25, 2023

(54) REDUCED PARASITIC RESISTANCE TWO-DIMENSIONAL MATERIAL FIELD-EFFECT TRANSISTOR

(71) Applicant: International Business Machines Corporation, Armonk, NY (US)

(72) Inventors: Kangguo Cheng, Schenectady, NY (US); Andrew Gaul, Halfmoon, NY (US); Julien Frougier, Albany, NY (US); Ruilong Xie, Niskayuna, NY (US)

(21) Appl. No.: 17/455,937

(22) Filed: Nov. 22, 2021

(51) Int. Cl. H01L 29/76; H01L 29/24; H01L 29/786; H01L 21/02; H01L 29/66

(52) U.S. Cl. CPC H01L 29/7606; H01L 29/24; H01L 29/78618; H01L 29/78696; H01L 21/02568; H01L 29/66969

(57) ABSTRACT

An approach to forming a field-effect transistor device formed with a two-dimensional material. The field-effect transistor device includes a channel composed of the two-dimensional material on a substrate and a high-k gate dielectric on the channel and extending under a sidewall spacer and around the sidewall spacer. The field-effect transistor includes a metal gate that is inside the high-k gate dielectric and over the channel. The source/drain is on a portion the two-dimensional material on the substrate. The source/drain abuts the sidewall spacer and is composed of a bi-layer metal.

### BACKGROUND OF THE INVENTION

The present invention relates generally to the field of semiconductor device formation and more particularly to forming a field-effect transistor using a 2-dimensional material for a channel and a bi-layer metal for the source/drain.

Continued innovations in semiconductor process technologies are enabling higher integration densities and device scaling. As the semiconductor industry moves beyond the five nanometer technology node and beyond, planar and non-planar semiconductor device structures, such as field-effect transistors (FETs) must be scaled to smaller dimensions to provide increased device width per footprint area.

The development of ultra-thin 2-dimensional (2D) materials for use semiconductor devices provides an avenue for reduced device spacing and smaller device dimensions. 2D materials are an emerging class of nanostructured low-dimensional materials with a great potential in fabricating the next generation of miniaturized electronics and optoelectronics devices. An example is graphene which has attracted substantial attention and led to extensive study in physics, materials, nano-engineering, and optoelectronic applications due to its extraordinary electrical properties such as high carrier mobility, broad absorption spectrum, and fast response time. However, a lack of a bandgap hinders its potential for electronic device applications leading to a great motivation in exploring other 2D layered materials. Among them, transition metal dichalcogenides (TMDs) such as MoS₂ and WS₂ have received considerable attention due to their exceptional properties including a direct bandgap in the visible range, large absorption coefficient, large exciton binding energy, and sensitivity to interlayer interactions.

### SUMMARY

Embodiments of the present invention disclose a field-effect transistor device formed with a two-dimensional material that includes a channel composed of a two-dimensional material on a substrate. The field-effect transistor device includes a high-k gate dielectric on the channel and extending under a sidewall spacer and around the sidewall spacer. The field-effect transistor has a metal gate inside the high-k gate dielectric and over the channel. Embodiments of the present invention disclose the field-effect transistor device with a source/drain on a portion of the two-dimensional material and abutting the sidewall spacer. Embodiments of the present invention provide a bi-layer metal for the source/drain.

Embodiments of the present invention disclose a second field-effect transistor device formed with a two-dimensional material for a channel. The channel is composed of a a thinner portion of the two-dimensional material on a substrate. A high-k gate dielectric material is on the channel and on a vertical portion of the two-dimensional material. The second field-effect transistor includes the metal gate on the high-k gate dielectric material above the channel. A source/drain is on a thicker portion of the two-dimensional material on the substrate. The source/drain abuts a bottom portion of a sidewall spacer. Embodiments of the present invention disclose that the source/drain is composed of a bi-layer metal. The vertical portion of the two-dimensional material is a thinner portion of the two-dimensional material that on a bottom portion of the sidewall spacer.

Embodiments of the present invention provide a method of forming a field-effect transistor channel with a two-dimensional material for a channel by depositing a layer of a two-dimensional material over a substrate with a non-conductive surface. The method includes depositing a layer of a first metal material over the two-dimensional material and depositing a layer of a second metal that is covered by a hardmask material over the first metal. The method includes removing a portion of the hardmask and a portion of the second metal. A sidewall spacer is formed on the second metal and the hardmask. The method includes removing exposed portions of the first metal and a portion of the first metal under the sidewall spacer and depositing a high-k gate dielectric material over exposed surfaces of the two-dimensional material, the sidewall spacer, and the hardmask. Furthermore, the method includes forming a metal gate inside the high-k dielectric material.

### BRIEF DESCRIPTION OF THE DRAWINGS

The above and other aspects, features, and advantages of various embodiments of the present invention will be more apparent from the following description taken in conjunction with the accompanying drawings.

FIG. 1 depicts a cross-sectional view of a semiconductor structure after depositing a two-dimensional (2D) material, a first metal, a second metal, and a hardmask (HM) on a substrate, in accordance with an embodiment of the present invention.

FIG. 2 depicts a cross-sectional view of the semiconductor structure after depositing a mask material and selectively removing a portion of the second metal and HM, in accordance with an embodiment of the present invention.

FIG. 3 depicts a cross-sectional view of the semiconductor structure after removing the mask and forming a sidewall spacer, in accordance with an embodiment of the present invention.

FIG. 4 depicts a cross-sectional view of the semiconductor structure after removing a portion of the first metal under the sidewall spacer, in accordance with an embodiment of the present invention.

FIG. 5 depicts a cross-sectional view of the semiconductor structure after depositing a high-k gate dielectric material over the semiconductor structure, in accordance with an embodiment of the present invention.

FIG. 6 depicts a cross-sectional view of the semiconductor structure after depositing and the planarizing metal gate, in accordance with an embodiment of the present invention.

FIG. 7 depicts a cross-sectional view of a semiconductor structure after depositing a 2D material, a first metal, a second metal, and a hardmask on a substrate, in accordance with a second embodiment of the present invention.

FIG. 8 depicts a cross-sectional view of the semiconductor structure after patterning a mask and removing portions of the hardmask, the second metal, and the first metal, in accordance with the second embodiment of the present invention.

FIG. 9 depicts a cross-sectional view of the semiconductor structure after removing the mask and forming a sidewall spacer, in accordance with the second embodiment of the present invention. gate structure, in accordance with an embodiment of the present invention.

FIG. 10 depicts a cross-sectional view of the semiconductor structure after removing a portion of the 2D material, in accordance with the second embodiment of the present invention.

FIG. 11 depicts a cross-sectional view of the semiconductor structure after depositing a second layer of the 2D material and a sacrificial material, in accordance with the second embodiment of the present invention

FIG. 12 depicts a cross-sectional view of the semiconductor structure after depositing and recessing an organic planarization layer (OPL), in accordance with the second embodiment of the present invention.

FIG. 13 depicts a cross-sectional view of the semiconductor structure after removing the exposed portion of the sacrificial material and the second 2D material on the sidewalls of the sidewall spacer, in accordance with the second embodiment of the present invention.

FIG. 14 depicts a cross-sectional view of the semiconductor structure after removing the OPL and sacrificial material, in accordance with the second embodiment of the present invention. gate structure, in accordance with an embodiment of the present invention.

FIG. 15 depicts a cross-sectional view of the semiconductor structure after depositing a layer of a high-k gate dielectric material and forming a metal gate, in accordance with an embodiment of the present invention.

### DETAILED DESCRIPTION

Embodiments of the present invention recognize that use nanosheet stacks is increasingly prevalent for device architecture and formation for continuing complementary metal-oxide-semiconductor (CMOS) devices. Embodiments of the present invention recognize that using nanosheet stacks is a primary driver in extending CMOS device scaling, however the use of nanosheet stacks for CMOS device scaling appears to be limited for extension beyond 40 nm gate pitch because of gate-to-gate pinch off that can commonly occur during inner spacer formation.

Embodiments of the present invention recognize that current CMOS device formation using nanosheet stacks with typical nanosheet silicon sheets for device channels (e.g., approximately five nm thick) limits gate pitch to the 40 nm range due to the short channel effect limitation of devices formed with current nanosheet stacks. Additionally, using current nanosheet stacks for devices prevents reducing the silicon channel thickness below current thicknesses of about 5 nm to improve electrostatic device control since quantum confinement effects begin to degrade device performance. Embodiments of the present invention recognize that providing a thinner channel to improve electrostatic control without initiating quantum confinement effects is desirable.

Embodiments of the present invention recognize that the use of two-dimensional (2D) materials to provide thinner channels is being explored. One of the main challenges for the use of 2D materials in transistor devices is high parasitic resistance occurring with the use of very thin 2D materials. 2D materials are a class of nanomaterials defined by their property of being merely one or several atoms thick. Examples of 2D material include but are not limited to graphene, a single-atom-thick hexagonal or honeycomb-arranged sheet of carbon atoms, silicene, molybdenum disulfide (MoS₂), boron, and germanene. Embodiments of the present invention recognize that the source/drain contact resistance is one source of the additional parasitic resistance occurring in devices formed with 2D materials.

Embodiments of the present invention provide a bi-layer metal for the source/drain of a field-effect transistor (FET) formed with a 2D material as a device channel. The field-effect device with the bi-layer metal source/drain reduces device parasitic resistance. Embodiments of the present invention provide a bi-layer metal source/drain that uses a first metal layer in contact with the 2D material that provides a lower contact resistance to the 2D metal than the second metal layer that is over the first metal in the bi-layer metal. The second metal is a low bulk resistivity metal. The combination of the first metal layer and the second metal layer in the bi-layer metal of the source/drain reduces the parasitic resistance and improves the functionality of the FET device formed with the 2D material as compared to previously disclosed FET devices formed using a 2D material.

Additionally, embodiments of the present invention disclose a semiconductor structure for the FET device formed with a channel composed of a 2D material where a high-k gate dielectric material extends under the sidewall spacer abutting high-k gate dielectric material surrounding the metal gate. The extension of the high-k gate dielectric material under the sidewall spacer provides better electrical coupling between the metal gate and the 2D material under the high-k gate dielectric material extension. The 2D material that is under the high-k gate dielectric extension is a portion of the 2D material layer that is in direct contact with the portion of the 2D material that is the channel of the FET device. In this way, the high-k gate dielectric extension under the sidewall spacer generates additional carriers in the 2D material under the high-k gate dielectric extension to improve FET device performance.

Embodiments of the present invention also provide a second FET device where the 2D material in the channel is a very thin layer of the 2D material to improve FET device electrostatics. The second FET device also includes a thicker 2D material under the source/drain to reduce external device electrical resistance.

Embodiments of the present invention disclose a method of forming a FET device with a 2D material channel and a bi-layer metal source/drain with a high-k gate dielectric extension that is under the sidewall spacer. The method includes depositing a very thin layer of a 2D material over a substrate with a non-conductive surface. The method includes depositing a layer of a first metal over the 2D material and depositing a layer of a second metal over the first metal, where the second metal is five to fifteen times thicker than the first metal. A hardmask is deposited over the second metal and a mask is deposited and patterned on the hardmask. The method includes removing a portion of the hardmask and the second metal and then, forming a sidewall spacer on the vertical sides of the remaining hardmask and second metal. A wet etch process, such as a sulfuric acid etch removes exposed portions of the first metal and laterally etches a portion of the first metal that extends under the sidewall spacer. The method includes conformally depositing a layer of high-k gate dielectric material over the exposed surfaces of the hardmask, the spacer, and the 2D material. Using a conformal deposition process, such as atomic layer deposition, the high-k gate dielectric material deposits in the undercut of the first metal that is below the sidewall spacer. The high-k gate dielectric material fills the undercut region forming an extension or high-k gate dielectric foot under the sidewall spacer. The method includes depositing a metal gate material and performing a planarization or polishing operation to form the metal gate on the high-k gate dielectric material above the 2D material channel of the FET device.

The following description with reference to the accompanying drawings is provided to assist in a comprehensive understanding of exemplary embodiments of the invention as defined by the claims and their equivalents. The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the industry, or to enable others of ordinary skill in the art to understand the embodiments disclosed herein. Accordingly, those of ordinary skill in the art will recognize that various changes and modifications of the embodiments described herein can be made without departing from the scope and spirit of the invention. Some of the process steps, depicted, can be combined as an integrated process step. In addition, descriptions of well-known functions and constructions may be omitted for clarity and conciseness.

The terms and words used in the following description and claims are not limited to the bibliographical meanings but are merely used to enable a clear and consistent understanding of the invention. Accordingly, it should be apparent to those skilled in the art that the following description of exemplary embodiments of the present invention is provided for illustration only and not for the purpose of limiting the invention as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces unless the context clearly dictates otherwise.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. Terms such as “above”, “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating, or semiconductor layers at the interface of the two elements.

In the interest of not obscuring the presentation of embodiments of the present invention, in the following detailed description, some processing steps or operations that are known in the art may have been combined for presentation and illustration purposes and in some instances may have not been described in detail. In other instances, some processing steps or operations that are known in the art may not be described at all. It should be understood that the following description is rather focused on the distinctive features or elements of various embodiments of the present invention.

Detailed embodiments of the claimed structures and methods are disclosed herein. The method steps described below do not form a complete process flow for manufacturing integrated circuits on semiconductor chips. The present embodiments can be practiced in conjunction with the integrated circuit fabrication techniques for semiconductor chips and devices currently used in the art, and only so much of the commonly practiced process steps are included as are necessary for an understanding of the described embodiments. The figures represent cross-section portions of a semiconductor chip or a substrate, such as a semiconductor wafer during fabrication, and are not drawn to scale, but instead are drawn to illustrate the features of the described embodiments. Specific structural and functional details disclosed herein are not to be interpreted as limiting, but merely as a representative basis for teaching one skilled in the art to variously employ the methods and structures of the present disclosure. In the description, details of well-known features and techniques may be omitted to avoid unnecessarily obscuring the presented embodiments.

References in the specification to “one embodiment”, “other embodiment”, “another embodiment”, “an embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to affect such feature, structure, or characteristic in connection with other embodiments whether or not explicitly described. It will be understood that, although the terms first, second, etc. can be used herein to describe various elements, these elements should not be limited by these terms. These terms are only used to distinguish one element from another element. Thus, the first element discussed below could be termed a second element without departing from the scope of the present concept.

Deposition processes for the metal materials and sacrificial material include, e.g., chemical vapor deposition (CVD), physical vapor deposition (PVD), atomic layer deposition (ALD), or gas cluster ion beam (GCIB) deposition. CVD is a deposition process in which a deposited species is formed as a result of a chemical reaction between gaseous reactants at greater than room temperature (e.g., from about 25 C to about 900 C.). The solid product of the reaction is deposited on the surface on which a film, coating, or layer of the solid product is to be formed. Variations of CVD processes include, but are not limited to, atmospheric pressure CVD (APCVD), low-pressure CVD (LPCVD), plasma Enhanced CVD (PECVD), and metal-organic CVD (MOCVD) and combinations thereof may also be employed. In alternative embodiments that use PVD, a sputtering apparatus may include direct-current diode systems, radio frequency sputtering, magnetron sputtering, or ionized metal plasma sputtering. In alternative embodiments that use ALD, chemical precursors react with the surface of a material one at a time to deposit a thin film on the surface. In alternative embodiments that use gas cluster ion beams (GCIB) deposition, the high-pressure gas is allowed to expand in a vacuum, subsequently condensing into clusters. The clusters can be ionized and directed onto a surface, providing a highly anisotropic deposition.

Selectively etching as used herein includes but is not limited to patterning using one of lithography, photolithography, an extreme ultraviolet (EUV) lithography process, or any other known semiconductor patterning process followed by one or more the etching processes. Various materials are referred to herein as being removed or “etched” where etching generally refers to one or more processes implementing the removal of one or more materials while leaving other protected areas of the materials that are masked during the lithography processes unaffected. Some examples of etching processes include but are not limited to the following processes, such as a dry etching process using a reactive ion etch (RIE) or ion beam etch (IBE), a wet chemical etch process, or a combination of these etching processes. A dry etch may be performed using a plasma. Ion milling, sputter etching, or reactive ion etching (RIE) bombards the wafer with energetic ions of noble gases that approach the wafer approximately from one direction, and therefore, these processes are an anisotropic or a directional etching process.

Reference is now made to the figures. The figures provide a schematic cross-sectional illustration of semiconductor devices at intermediate stages of fabrication, according to one or more embodiments of the invention. The device provides schematic representations of the devices of the invention and they are not to be considered accurate or limiting with regards to device element scale.

FIG. 1 depicts a cross-sectional view of a semiconductor structure after depositing 2D material 2, first metal 3, second metal 4, and hardmask (HM) 5 on substrate 1, in accordance with an embodiment of the present invention. In various embodiments, substrate 1 is a semiconductor substrate, wafer, or a portion of a wafer with an oxide layer, such as a silicon substrate with an insulating layer of silicon dioxide (SiO₂). Substrate 1 or the surface of substrate 1 is composed of an electrically insulating material. Substrate 1 can be composed of any non-conductive material that provides sufficient mechanical properties (e.g., rigidity, chemical resistance, flatness, ability to withstand semiconductor processing temperatures, etc.) for forming a field-effect transistor (FET) using 2D material 2.

2D material 2 can be any 2D semiconductor material currently used or under development for use as channels in FET devices. Using a 2D material for a FET channel provides a thinner channel than can be provided with a silicon-based material channel. Using the thinner channel provided by 2D material 2 can improve gate pitch between adjacent FET devices. For example, 2D material 2 can be a transition metal dichalcogenide material, where the transition metals are from group VI, V and VI in the Periodic Table of Elements, and a di-chalcogen can be two molecules of a chalcogen material such as sulfur, selenium, or tellurium but 2D material 2 is not limited to these materials. 2D material 2 can be one of MoSe2, MoTe2, WS2, and WSe2 but may be composed of a different 2D material in other embodiments. A very thin layer of 2D material 2 can be deposited, for example, using ALD but is not limited to this deposition process. The thickness of 2D material 2 can range between 0.7 nm and 3 nm but is not limited to these thicknesses. In various embodiments, As depicted, 2D material 2 resides on substrate 1.

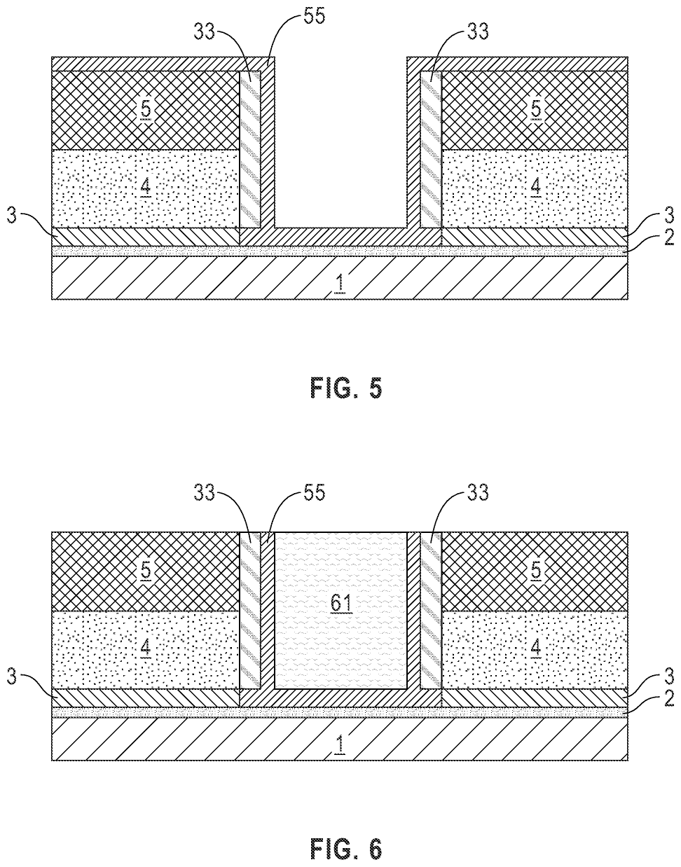

First metal 3 resides on 2D material 2. First metal 3 can be a metal material with a low electrical contact resistivity with 2D material 2. For example, first metal 3 has a lower electrical contact resistivity with 2D material 2 than second metal. In various embodiments, first metal 3 is bismuth (Bi) but is not limited to this metal material. First metal 3 may be deposited, for example by ALD. The thickness of first metal 3 can be approximately 3 nm but may be thinner or thicker in other examples. In some embodiments, the thickness of first metal 3 should be less than or equal to two times of the thickness of the high-k gate dielectric. First metal 3 needs to provide a thin enough layer to allow the pinch-off of the high-k gate electrode deposited later in FIG. 5.

Second metal 4 is a metal material with a low bulk resistivity. Second metal 4 will form a portion of the source/drain contacts for the FET device. For example, second metal 4 can be tungsten which may include a liner material (e.g., titanium nitride) but second metal 4 may be another metal material with a low bulk resistivity that is compatible with semiconductor processing and FET operation and applications. Second metal 4 and first metal 3 can form a bi-layer metal structure for the source/drain of the FET device. Second metal 4 can be thicker than first metal 3 and can have a thickness ranging from 15 nm to 50 nm but is not limited to these thicknesses. Second metal 4 may be deposited by one of PVD, CVD, or ALD, for example.

HM 5 resides on second metal 4. HM 5 can be any hardmask material, such as but not limited to SiN. HM 5 can be deposited by any known hardmask deposition methods, such as CVD, PVD, etc.

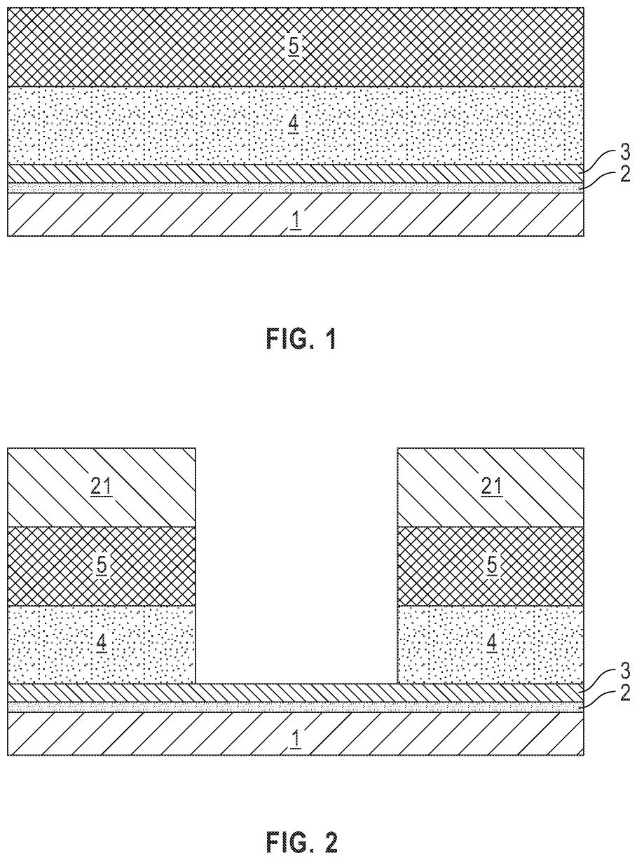

FIG. 2 depicts a cross-sectional view of the semiconductor structure after depositing a mask material and selectively removing a portion of second metal 4 and HM 5, in accordance with an embodiment of the present invention. As depicted, FIG. 2 includes substrate 1, 2D material 2, first metal 3, second metal 4, HM 5, and mask 21. As depicted, a patterned mask 21 remains over the remaining portions of HM 5 and second metal 4 after the etching process. Mask 21 can be any suitable mask material used in semiconductor processes (e.g., a resist, a soft mask, etc.).

Using an anisotropic etching process, such as RIE, a portion of HM 5 and second metal 4 is removed above first metal 3. First metal 3 serves as a buffer protecting 2D material 2 during the etching process. The portion of HM 5 and second metal 4 are removed above what will become the channel area in 2D material 2 after later processing steps.

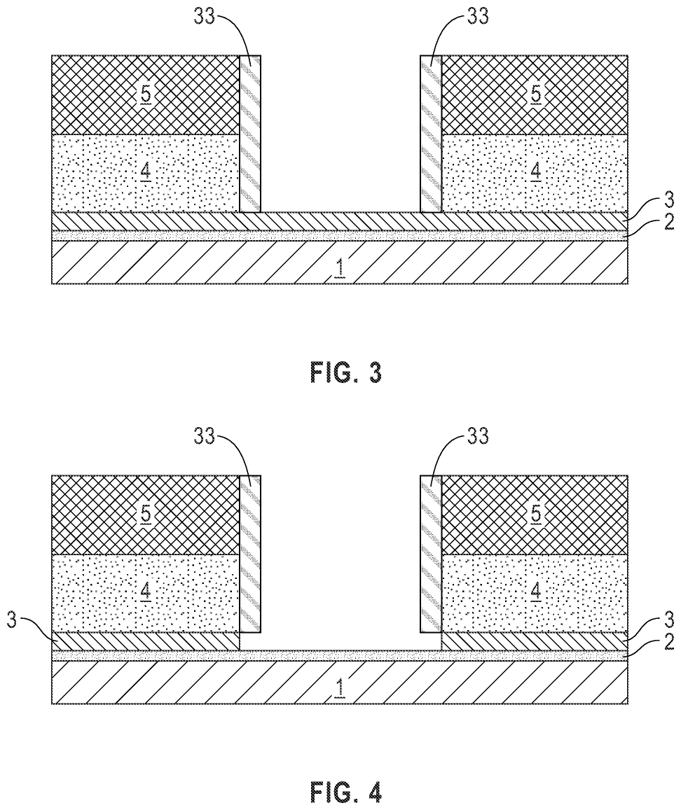

FIG. 3 depicts a cross-sectional view of the semiconductor structure after removing mask 21 and forming spacer 33, in accordance with an embodiment of the present invention. As depicted, FIG. 3 includes the elements of FIG. 2 without mask 21 and with spacer 33.

In various embodiments, spacer 33 is a sidewall spacer deposited using a conformal deposition process, such as ALD or CVD. Spacer 33 can be composed of any known sidewall spacer materials used in FET devices. For example, spacer 33 may be composed of a dielectric material. Some examples of the spacer material include, but are not limited to, silicon nitride (SiN), silicon carbide (SiC), silicon oxynitride (SiON), carbon-doped silicon oxide (SiOC), fluorine-doped silicon oxide (SiO:F), silicon-carbon-nitride (SiCN), boron nitride (BN), silicon boron nitride (SiBN), silicoboron carbonitride (SiBCN), silicon oxycabonitride (SiOCN), silicon oxide, and combinations thereof. The dielectric material can be a low-k material having a dielectric constant less than about 7, and preferably, less than about 5. Spacers 33 can be formed by any suitable techniques such as deposition followed by directional etch. Deposition may include but is not limited to, atomic layer deposition (ALD), chemical vapor deposition (CVD). Directional etch may include but is not limited to, reactive ion etch (RIE).

Spacer 33 can be deposited with a horizontal width that is approximately 5 nm. In some examples, the horizontal width of spacer 33 on the sidewalls of second metal 4 and HM 5 can thinner or thicker. Using known spacer formation processes, the portions of spacer 33 on exposed horizontal surfaces of first metal 3 and HM 5 can be removed by RIE to a sidewall spacer for spacer 33.

FIG. 4 depicts a cross-sectional view of the semiconductor structure after removing a portion of first metal 3 under spacer 33, in accordance with an embodiment of the present invention. Using an isotropic etching process (e.g., wet etching process) with a chemistry that is selective to spacer 33, a portion of first metal 3 under spacer 33. For example, sulfuric acid may be used to etch the portion of first metal 3 under spacer 33. As depicted in FIG. 4, the lateral etch undercuts or removes the portion of first metal 3 under spacer 33. The lateral undercut extends horizontally to the edge of second metal 4 abutting spacer 33.

FIG. 5 depicts a cross-sectional view of the semiconductor structure after depositing high-k dielectric 55 over the semiconductor structure, in accordance with an embodiment of the present invention. As depicted, FIG. 5 includes the elements of FIG. 4 and high-k dielectric 55. High-k dielectric 55 can be composed of any suitable material used for a high-k gate dielectric material in complementary metal-oxide-semiconductor (CMOS) processes and devices. For example, high-k gate dielectric 55 can be one of but are not limited to metal oxide materials such as hafnium oxide (e.g., HfO₂), a hafnium silicon oxide, a hafnium silicon oxynitride (e.g., HfSiON), a lanthanum oxide (e.g., La₂O₃), a tantalum oxide (e.g., TaO), titanium oxide (e.g., TiO), and any other suitable high-k dielectric material. In some embodiments, high-k dielectric 55 may include dopants such as lanthanum, aluminum, magnesium. Using a conformal deposition process, such as ALD or CVD, a layer of high-k dielectric 55 is deposited over exposed surfaces of HM 5, 2D material 2, around and under spacer 33. The undercut area adjacent to 2D material 2 and under spacer 33 is pinched off and filled during the conformal deposition of high-k dielectric 55. Filling the undercut region beneath spacer 33 with high-k dielectric 55 provides stronger coupling for the gate electrode deposited later with 2D material 2. High-k dielectric 55 may have a thickness on HM 5 that is fairly thin and may be in the range of 1.5 nm to 10 nm but is not limited to this range. As depicted, high-k dielectric 55 does not extend under the source/drain composed of first metal 3 and second metal 4.

FIG. 6 depicts a cross-sectional view of the semiconductor structure after depositing and planarizing metal gate 61, in accordance with an embodiment of the present invention. As depicted, FIG. 6 includes the elements of FIG. 5 and metal gate 61 inside high-k dielectric 55. Metal gate 61 is over high-k dielectric 55 and in various embodiments, metal gate 61 can comprise any suitable conducting material, including but not limited to, doped polycrystalline or amorphous silicon, germanium, silicon germanium, a metal (e.g., tungsten (W), titanium (Ti), tantalum (Ta), ruthenium (Ru), hafnium (Hf), zirconium (Zr), cobalt (Co), nickel (Ni), copper (Cu), aluminum (Al), platinum (Pt), tin (Sn), silver (Ag), gold (Au), a conducting metallic compound material (e.g., tantalum nitride (TaN), titanium nitride (TiN), tantalum carbide (TaC), titanium carbide (TiC), titanium aluminum carbide (TiAlC), tungsten silicide (WSi), tungsten nitride (WN), ruthenium oxide (RuO₂), cobalt silicide (CoSi), nickel silicide (NiSi)), transition metal aluminides (e.g. Ti₃Al, ZrAl), TaMgC, carbon nanotube, conductive carbon, graphene, or any suitable combination of these materials. The conductive material may further comprise dopants that are incorporated during or after deposition. In some embodiments, the gate may further comprise a workfunction setting layer between the gate dielectric and gate conductor. The workfunction setting layer can be a workfunction metal (WFM). WFM can be any suitable material, including but not limited to a nitride, including but not limited to titanium nitride (TiN), titanium aluminum nitride (TiAlN), hafnium nitride (HfN), hafnium silicon nitride (HfSiN), tantalum nitride (TaN), tantalum silicon nitride (TaSiN), tungsten nitride (WN), molybdenum nitride (MoN), niobium nitride (NbN); a carbide, including but not limited to titanium carbide (TiC) titanium aluminum carbide (TiAlC), tantalum carbide (TaC), hafnium carbide (HfC), and combinations thereof. In some embodiments, a conductive material or a combination of multiple conductive materials can serve as both gate conductor and WFM. The gate conductor and WFM can be formed by any suitable process or any suitable combination of multiple processes, including but not limited to, atomic layer deposition (ALD), chemical vapor deposition (CVD), physical vapor deposition (PVD), sputtering, plating, evaporation, ion beam deposition, electron beam deposition, laser-assisted deposition, chemical solution deposition, etc. Metal gate 61 may be deposited using ALD, CVD, or PVD. After metal gate 61 deposition on high-k dielectric 55 and HM 5, a chemical mechanical planarization (CMP) process can occur to remove portions of metal gate 61 and high-k dielectric 55 above HM 5. After the CMP, FIG. 6 includes metal gate 61 inside high-k dielectric 55, high-k dielectric 55 under metal gate 61 and spacer 33. High-k dielectric 55 is along or abuts the inside vertical sidewalls of spacer 33. 2D material 2 resides on substrate 1 under first metal 3, and high-k dielectric 55. The source/drain can be composed of first metal 3 and second metal 4 while the channel is in 2D material 2 under metal gate 61 (e.g., under high-k dielectric 55 that is under metal gate 61).

The semiconductor structure depicted in FIG. 6 can be a FET device with a channel composed of 2D material 2 under metal gate 61 and high-k dielectric 55. The area of 2D material 2 under spacer 33 may be considered as an extension region or a high-k footing for metal gate 61. The footing or the portion of high-k dielectric 55 that is under spacer 33 and over 2D material 2 can enhance the gate fringing effect. The gate fringing capacitance increases with the increasing dielectric constant of the material above 2D material 2 and adjacent to but not under metal gate 61. By undercutting spacer 33 and replacing the removed portion of spacer 33 which is a relatively low-k dielectric spacer material (e.g., SiOC) and replacing spacer 33 with high-k dielectric 55 under spacer 33 and above 2D material 2 (adjacent to metal gate 61) increases gate fringing capacitance. This novel semiconductor structure enhances the gate fringing field at the bottom corners of metal gate 61 to increase carrier density under spacer 33 in 2D material 2 (e.g., in the extension region of 2D material 2). With increasing carrier density, the resistance in the extension region of 2D material 2 under high-k dielectric 55 and spacer 33 decreases. Additionally, using a low-k dielectric material for spacer 33 can minimize the parasitic capacitance between metal gate 61 and the source/drains formed in first metal 3 and second metal 4.

The remaining portions of first metal 3 and second metal 4 form the source and the drain for the FET device. Using a bi-layer metal structure for the FET device source/drain regions where first metal 3 provides a lower contact resistivity with 2D material 2 and the second metal of the bi-layer metal is a metal with a low bulk resistivity reduces the parasitic resistance of the FET device using a 2D-channel material. For example, second metal 4 has a lower bulk resistivity than first metal 3.

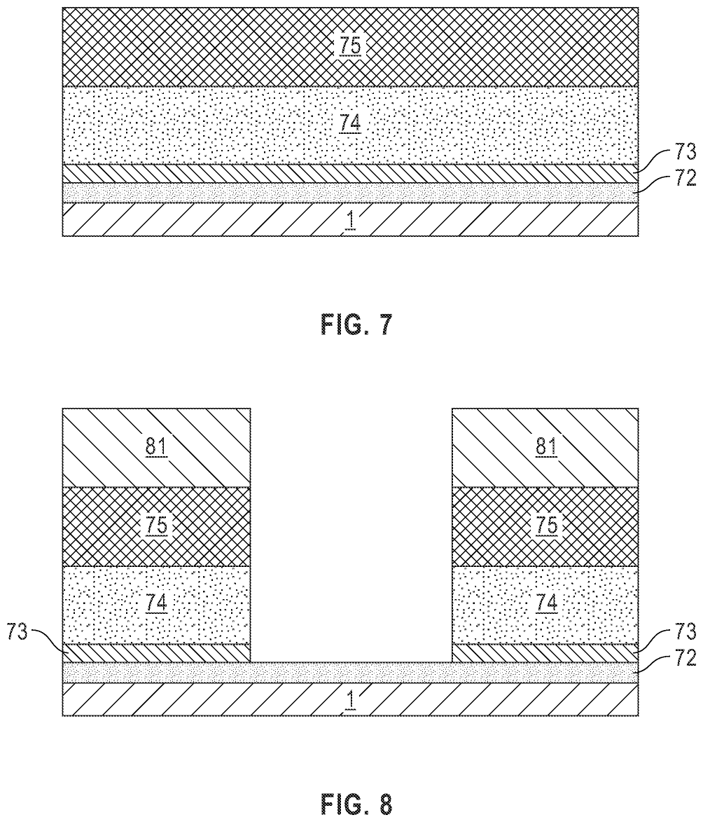

FIG. 7 depicts a cross-sectional view of a semiconductor structure after depositing 2D material 72, first metal 73, second metal 74, and hardmask 75 on substrate 1, in accordance with a second embodiment of the present invention. 2D material 72, first metal 73, second metal 74, and hardmask 75 are essentially the same as 2D material 2, first metal 73, second metal 74, and HM 5 and may be deposited with one of the processes and materials discussed in detail with respect to FIG. 1. 2D material 72 may be composed of the same 2D material as 2D material 2 or a different 2D material and may be deposited with one of the processes (e.g., ALD or CVD) discussed with respect to FIG. 1. The thickness of 2D material 72 is greater than the thickness of 2D material 2. For example, the thickness of 2D material 72 may be 5 nm to 30 nm but is not limited to these thicknesses.

FIG. 8 depicts a cross-sectional view of the semiconductor structure after patterning mask 81 and removing portions of hardmask 75, second metal 74, and first metal 73, in accordance with the second embodiment of the present invention. Mask 81 can be a mask material similar to or the same as mask 21 in FIG. 2. After patterning mask 81, using a RIE, for example, a portion of hardmask 75, second metal 74, and first metal 73 are removed above 2D material 72.

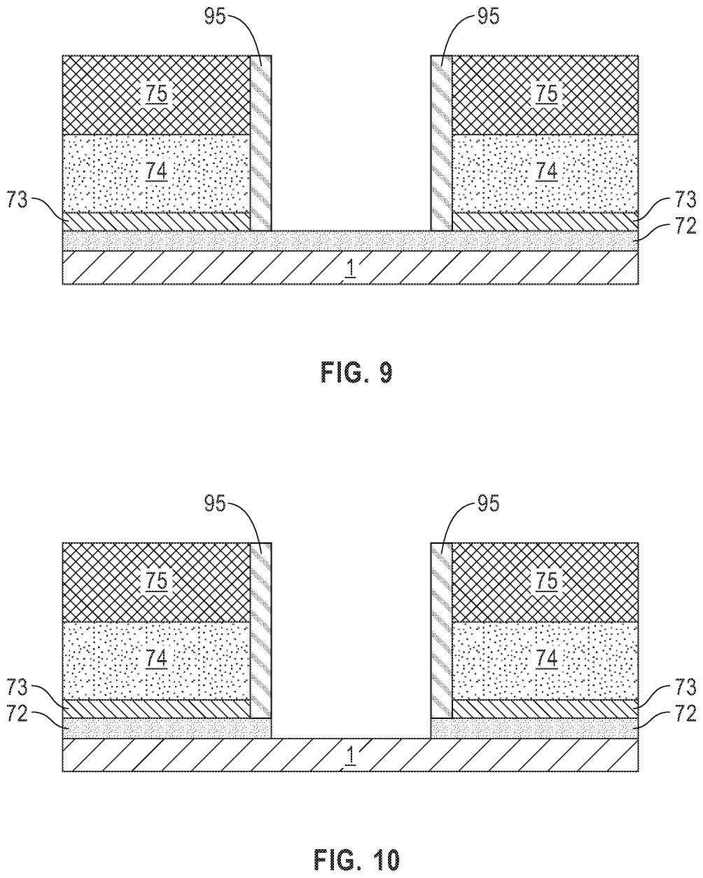

FIG. 9 depicts a cross-sectional view of the semiconductor structure after removing mask 81 and forming spacer 33, in accordance with the second embodiment of the present invention. Using known sidewall spacer formation processes previously discussed with respect to FIG. 3, a dielectric material, such as but not limited to SiN, SiC, SiON, SiOC, or any of the spacer materials discussed with respect to FIG. 3 can be deposited over the semiconductor structure with a conformal deposition process (e.g., ALD). An RIE removes the spacer material from the top surfaces of HM 5 and 2D material 72 to form spacer 95 along exposed vertical surfaces of first metal 73, second metal 74, and hardmask 75. Similar to spacer 33, the horizontal width of spacer 95 may be approximately 5 nm but the width of spacer 95 may be more in some cases or slightly less.

FIG. 10 depicts a cross-sectional view of the semiconductor structure after removing a portion of 2D material 72, in accordance with the second embodiment of the present invention. For example, using a plasma etch process containing SF₆+N₂ plasma or an RIE, exposed portions of 2D material 72 are removed. After the etching process, a portion of the top surfaces of substrate 1 is exposed.

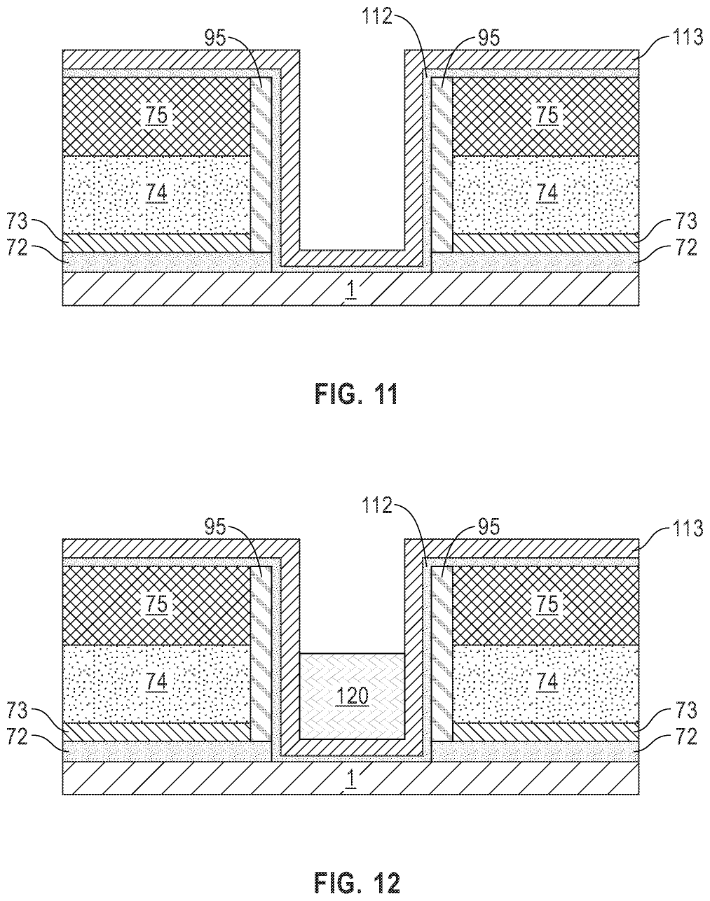

FIG. 11 depicts a cross-sectional view of the semiconductor structure after depositing 2D material 112 and sacrificial material 113, in accordance with an embodiment of the present invention. A second, very thin layer of a 2D material is deposited over the semiconductor structure (e.g., over a portion of substrate 1, 2D material 112, spacer 95, and hardmask 75). In various embodiments, 2D material 112 is the same material as 2D material 72. In one embodiment, 2D material 112 is a different 2D material than 2D material 72. In some embodiment, the thickness of 2D material 112 is substantially thinner than the thickness of 2D material 72. A part of the 2D material 112 (e.g., horizontal portion in FIG. 11) will become the channel of the 2D transistor. Keeping 2D material 112 thin helps achieve good electrostatics of 2D transistors. Meanwhile, thicker 2D material 72 helps reduce the external resistance. The thickness of 2D material 112 over substrate 1 can range between 0.7 nm and 3 nm but is not limited to this range. As deposited, 2D material 112 is over exposed surfaces of substrate 1, 2D material 72, spacer 95, and hardmask 75. 2D material 112 resides over the top surfaces of hardmask 75, spacer 95, substrate 1, and along the exposed vertical sides of spacer 95 and 2D material 72.

A layer of sacrificial material 113 is deposited over 2D material 112, for example using PVD, CVD, or ALD. The thickness of sacrificial material 113 may be 3 nm to 10 nm. Sacrificial material 113 can be a metal nitride, such as TiN or another sacrificial material that can protect the bottom portion or corners of 2D material 112 when a top portion of 2D material 112 is removed along spacer 95 (e.g., prevents potential shorting of 2D material 112 with contacts or metal layers formed after and the FET device during back end of the line processes).

FIG. 12 depicts a cross-sectional view of the semiconductor structure after depositing and recessing organic planarization layer (OPL) 120, in accordance with the second embodiment of the present invention. As depicted, FIG. 12 includes a remaining portion of OPL 120 inside sacrificial material 113, 2D material 112, spacer 95, hardmask 75, second metal 74, first metal 3, 2D material 72, and substrate 1. OPL 120 is deposited on sacrificial material 113. Using known OPL removal processes, the top portion of OPL 120 is removed from sacrificial material 113 above hardmask 75 and from a top vertical portion of sacrificial material 113 on spacer 95. After recessing OPL 120, a bottom portion of OPL 120 remains inside sacrificial material 113 covering at least a portion of the sidewall of spacer 95. The amount of OPL 120 remaining is not critical to the FET device formation as long as at least 10% or 15% of spacer 95 sidewall is covered, for example.

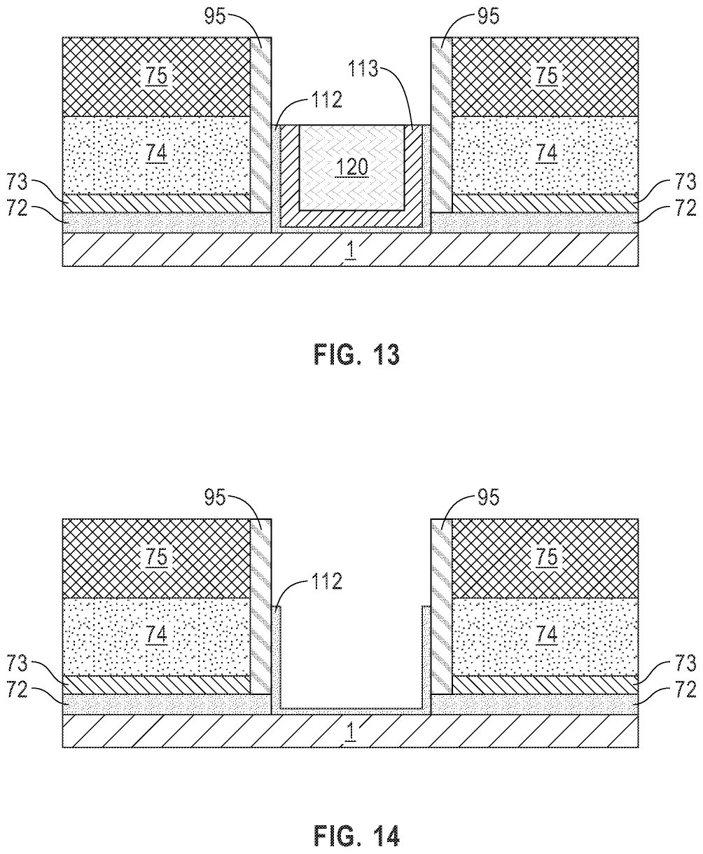

FIG. 13 depicts a cross-sectional view of the semiconductor structure after removing exposed portions of sacrificial material 113 and 2D material 112 from the top surface of hardmask 75 and the top portions of spacer 95, in accordance with the second embodiment of the present invention. Using an etching process, such as a plasma etch process containing SF₆+N₂ plasma, exposed portions of sacrificial material 113 and 2D material 112 are removed. Sacrificial material 113 and 2D material 112 can be removed from the top surface of hardmask 75. 2D material 112 and sacrificial material 113 are removed from the top surface spacer 95 and from the top portion of the vertical sidewalls of spacer 95, as depicted. The etching process exposes a top portion of spacer 95 and hardmask 75 along with the top surfaces of 2D material 112 and sacrificial material 113 and OPL 120. The height of the remaining sacrificial material 113 and 2D material 112 is the same as the top surface of OPL 120.

FIG. 14 depicts a cross-sectional view of the semiconductor structure after removing OPL 120 and sacrificial material 113, in accordance with the second embodiment of the present invention. Using conventional methods, OPL 120 is stripped to expose sacrificial material 113. Sacrificial material 113 can be removed using a wet etching solution containing ammonia and hydrogen peroxide, for example. After removing sacrificial material 113, a portion of the very thin layer of 2D material 112 remains on substrate 1 and over a bottom portion of the sidewalls of spacer 95 as depicted in FIG. 14.

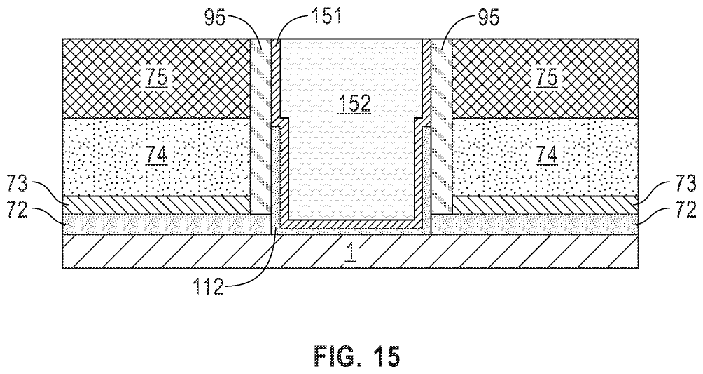

FIG. 15 depicts a cross-sectional view of the semiconductor structure after depositing a layer of high-k gate dielectric 151 and metal gate 152, in accordance with an embodiment of the present invention. As depicted, FIG. 15 includes metal gate 152 inside high-k gate dielectric 151, spacer 95, 2D material 112 on a portion of substrate 1, and on a bottom portion of spacer 95, hardmask 75 over the bi-layer metal structure of second metal 74 and first metal 73 from a source/drain region of the FET device, and 2D material 72 under first metal 73. As depicted, 2D material on a central portion of substrate 1 forming the device channel and along a bottom portion of spacer 95 is thinner than 2D material 72 abutting 2D material 112 and on substrate 1 under first metal 73. Using the processes as discussed in FIGS. 9-15, a thinner layer of 2D material can form the device channel while leaving a thicker layer of 2D material under the bi-layer metal source/drain (e.g., first metal 73 and second metal 74).

High-k gate dielectric 151 can any of the high-k materials previously discussed with respect to FIG. 5. For example, high-k gate dielectric 151 can be HfO₂. High-k gate dielectric 151 may be deposited with ALD or CVD with a thickness ranging from 1.5 nm to 10 nm but is not limited to this range. Metal gate 152 may be deposited using PVD, CVD, or ALD with one of metal gate the materials (e.g., W) previously discussed with respect to FIG. 6. In an embodiment, a work function metal is deposited with metal gate 152. After depositing metal gate 152, a CMP removes excess gate materials (e.g., high-k gate dielectric 151 and metal gate 152) from the top surface of hardmask 75. The very thin layer of 2D material 112 forms the channel of the FET device depicted in FIG. 15. As depicted, the thinner layer of the 2D material 112 extends vertically on a bottom portion of spacer 95. High-k dielectric 151 covers the top portion of spacer 95 and the vertical portions of 2D material 112. The source/drain of the FET device are formed by the two remaining portions of second metal 74 and first metal 73 (e.g., a bi-layer metal for the source/drain). A chemical mechanical polish (CMP) removes the portions of high-k dielectric 151 and metal gate 152 that are above hardmask 75.

The remaining portions of 2D material 72 form a thicker layer of the 2D material in the source/drain region and in the gate extension region under spacer 95 to reduce external electrical resistance. The thinner layer of 2D material 112 in the channel region of the FET device is under high-k gate dielectric 151 and metal gate 152. The thinner 2D material for the channel improves the electrostatics of the FET device formed with 2D materials.

The methods described herein can be used in the fabrication of integrated circuit chips or semiconductor chips. The resulting semiconductor chips can be distributed by the fabricator in raw wafer form (that is, as a single wafer that has multiple unpackaged chips), as a bare die, or in a packaged form. In the latter case, the semiconductor chip is mounted in a single chip package (such as a plastic carrier, with leads that are affixed to a motherboard or other higher-level carrier) or in a multichip package (such as a ceramic carrier that has either or both of surface interconnections or buried interconnections). In any case, the semiconductor chip is then integrated with other semiconductor chips, discrete circuit elements, and/or other signal processing devices as part of either (a) an intermediate product, such as a motherboard, or (b) an end product. The end product can be any product that includes semiconductor chips, ranging from toys and other low-end applications to advanced computer products having a display, memory, a keyboard or other input device, and a central processor.

What is claimed is:

1. A field-effect transistor device formed with a two-dimensional material, the field-effect transistor device comprising:
a channel composed of a first portion of a two-dimensional material on a substrate;
a high-k gate dielectric on the channel extends under a sidewall spacer and along the sidewall spacer;
a metal gate inside the high-k gate dielectric and over the channel; and
a source/drain on a second portion of the two-dimensional material on the substrate.

2. The field-effect transistor device of claim 1, wherein the source/drain on the first portion of the two-dimensional material is composed of a bi-layer metal.

3. The field-effect transistor device of claim 1, wherein the source/drain on the second portion of the two-dimensional material is composed of a first metal on the second portion of the two-dimensional material with a lower electrical contact resistivity with the two-dimensional material than a second metal that is on the first metal.

4. The field-effect transistor device of claim 3, wherein the second metal has a lower bulk resistivity than the first metal.

5. The field-effect transistor device of claim 3, wherein the first metal has a thickness less than two times a thickness of the high-k gate dielectric.

6. The field-effect transistor device of claim 1, wherein the high-k gate dielectric on the channel extends under the sidewall spacer does not go under the source/drain abutting the sidewall spacer.

7. A field-effect transistor device formed with a two-dimensional material, the field-effect transistor device comprising:
a channel composed of a thinner portion of a two-dimensional material on a substrate;
a high-k gate dielectric material on the channel and on a vertical portion of the two-dimensional material that is on a bottom portion of a sidewall spacer;
a metal gate on the high-k gate dielectric material above the channel; and
a source/drain on a thicker portion of the two-dimensional material on the substrate.

8. The field-effect transistor device of claim 7, wherein the vertical portion of the two-dimensional material that is on the bottom portion of the sidewall spacer is composed of a thinner vertical portion of the two-dimensional material.

9. The field-effect transistor device of claim 7, wherein the vertical portion of the two-dimensional material that is on the sidewall spacer is a thinner vertical portion of the two-dimensional material.

10. The field-effect transistor device of claim 7, wherein source/drain on the thicker portion of the two-dimensional material is composed of a bi-layer metal.

11. The field-effect transistor device of claim 7, wherein the source/drain on the thicker portion of the two-dimensional material on the substrate is composed of a first metal on the two-dimensional material with a lower electrical contact resistivity with the two-dimensional material than a second metal that is on the first metal.

12. The field-effect transistor device of claim 11, wherein the second metal has a lower bulk resistivity than the first metal.

13. The field-effect transistor device of claim 11, wherein the first metal has a thickness less than two times a thickness of the high-k gate dielectric.

14. The field-effect transistor device of claim 7, wherein the metal gate on the high-k gate dielectric material above the channel is inside the high-k dielectric material on the vertical portion of the two-dimensional material on the sidewall spacer.

15. A method of forming a semiconductor structure with a two-dimensional material for a field-effect transistor channel, the method comprising:
depositing a layer of a two-dimensional material over a substrate with a non-conductive surface;
depositing a layer of a first metal material over the two-dimensional material;
depositing a layer of a second metal covered by a hardmask material over the first metal;
removing a portion of the hardmask and the second metal;
forming a sidewall spacer on the second metal and the hardmask;
removing exposed portions of the first metal and a portion of the first metal under the sidewall spacer;
depositing a high-k gate dielectric material over exposed surfaces of the two-dimensional material, the sidewall spacer, and the hardmask; and
forming a metal gate.

16. The method of claim 15, wherein depositing a high-k gate dielectric material over exposed surfaces of the two-dimensional material, the sidewall spacer, and the hardmask, further comprises using a conformal deposition process to pinch off a portion of the high-k dielectric material under the sidewall spacer.

17. The method of claim 15, wherein the first metal material over the two-dimensional material has a lower electrical contact resistivity with the 2-dimensional material than the second metal material.

18. The method of claim 15, wherein the layer of the first metal material over the two-dimensional material is thinner than the layer of the second metal material.

19. The method of claim 15, wherein the layer of the first metal material over the two-dimensional material and the layer of the second metal material form a source/drain for a field-effect transistor.

20. The method of claim 19, the two-dimensional material under the high-k gate dielectric material beneath the metal gate is a channel for the field-effect transistor.
